(19) United States
(12) Patent Application Publication
(10) Pub. No.: US 2023/0130923 A1
(43) Pub. Date: Apr. 27, 2023

(54) SEMICONDUCTOR PACKAGE DEVICE AND METHOD FOR MANUFACTURING SEMICONDUCTOR PACKAGE DEVICE

(71) Applicant: SHUNSIN TECHNOLOGY (ZHONG SHAN) LIMITED, Zhongshan (CN)

(72) Inventor: SHUN-HSING LIAO, Zhongshan City (CN)

(21) Appl. No.: 17/552,911

(22) Filed: Dec. 16, 2021

(30) Foreign Application Priority Data
Oct. 22, 2021 (CN) 202111235814.X

(51) Int. Cl. H01L 23/373; H01L 21/48; H01L 23/498; H01L 25/16

(52) U.S. Cl. CPC H01L 23/3735; H01L 21/4853; H01L 23/49822; H01L 21/4857; H01L 25/16; H01L 23/3128

(57) ABSTRACT

A miniaturized and high-power semiconductor package device with its own heat-dissipating ability includes a heat conducting carrier, a redistribution layer, an electronic device, electronic components, a molding layer, and a solder ball. The heat conducting carrier includes an opening. The redistribution layer is formed on the heat conducting carrier. The redistribution layer has a circuit layer. The electronic device and the electronic components are disposed on a first surface of the redistribution layer away from the heat conducting carrier. The molding layer surrounds the electronic device and covers the electronic component. The solder balls are disposed in the opening, are in contact with a second surface of the redistribution layer opposite to the first surface, and are electrically connected to the circuit layer.

### FIELD

The subject matter herein generally relates to temperature control in semiconductor package devices and methods of manufacturing the semiconductor package devices.

### BACKGROUND

As the functions of instruments increase, semiconductor devices not only become smaller but also consume more electrical energy. Therefore, there is a need for a miniaturized packaging structure, which not only can reduce the relevant packaging size, but also has temperature control, for reliability.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a schematic cross-sectional diagram of a semiconductor package device according to an embodiment of the disclosure;

FIG. 2 is a schematic cross-sectional diagram of a semiconductor package device according to another embodiment of the disclosure;

FIG. 3 is a schematic diagram of the semiconductor package device with heat dissipation configuration according to an embodiment of the disclosure; and

FIGS. 4A, 4B, 4C, 4D, 4E and 4F are schematic cross-sectional diagrams illustrating a process flow of a method of manufacturing a semiconductor package device according to an embodiment of the disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one”.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

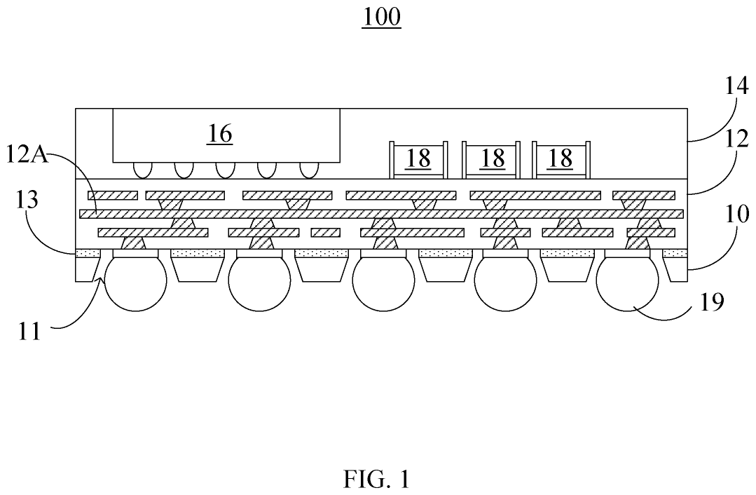

FIG. 1 illustrates a semiconductor package device (semiconductor package device 100) according to an embodiment of the disclosure. The semiconductor package device 100 comprises a heat conducting carrier 10, a redistribution layer 12, a molding layer 14, an electronic device 16, electronic components 18, and solder balls 19 for electrical connection purposes. The heat conducting carrier 10 is formed of a material with high thermal conductivity, and the thermal conductivity can be in the range of 50 to 5300 W/mK. According to an embodiment of the disclosure, the material of the heat conducting carrier 10 may comprise ceramic, graphene, graphite, carbon nanotube (CNT), carbon nanoball, and aluminum nitride (AlN), or a combination thereof. The heat conducting carrier 10 has an opening 11. The opening 11 can be formed by mechanical drilling, etching, or laser drilling.

The redistribution layer 12 is formed on the heat conducting carrier 10 and has a circuit layer 12A. According to an embodiment of the disclosure, the redistribution layer 12 can be formed layer by layer on the heat conducting carrier 10. In another embodiment, the redistribution layer 12 can be formed on a carrier first, then the carrier is removed after the redistributed layer 12 is coupled to the heat conducting carrier 10. The formation of the redistribution layer 12 may involve multiple deposition or coating processes, patterning processes, and planarization processes. The deposition or coating processes can be used to form insulating layers or the circuit layers 12A. The deposition or coating processes may comprise a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the formed insulating layers and circuit layers 12A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the formed insulating layers and circuit layers 12A to facilitate subsequent processes. The planarization process may comprise a mechanical polishing process, a chemical mechanical polishing (CMP) process, or other applicable processes and combinations thereof.

The redistribution layer 12 can also be formed by an additive buildup process. The additive buildup process may comprise the alternating stacking of one or more dielectric layers and corresponding conductive patterns or traces of the circuit layers 12A. The conductive patterns or traces fan the electrical traces out of the occupied space of the electronic device, or are in a fan-shaped layout allowing the electrical traces into the occupied space of the electronic device. The conductive patterns can be formed by a plating process such as an electroplating process or an electroless plating process. The conductive pattern may comprise a conductive material, such as copper or other plateable metals. The dielectric layer of the redistribution layer 12 can be made of a photo-definable organic dielectric such as polyimide (PI), benzocyclobutene (BCB), or polybenzoxazole (PBO). In other embodiments, the dielectric material of the redistribution layer 12 may also be an inorganic dielectric layer. The inorganic dielectric layer may comprise silicon nitride (Si₃N₄), silicon oxide (SiO₂), or SiON. The inorganic dielectric layer can be formed by growing an inorganic dielectric layer using an oxidation or nitridation process.

According to the embodiment of the disclosure, the redistribution layer 12 may further comprise a carrier, for example, a printed circuit board (PCB) or a laminated substrate. The carrier can be formed by laminating and build-up methods, which are wholly conventional and will be fully appreciated by those of ordinary skill in the art. The material of the dielectric structure inside the carrier may comprise epoxy resin, phenolic resin, glass epoxy resin, polyimide, polyester, epoxy molding compound, or ceramic. The material of the wires inside the carrier may comprise copper, iron, nickel, gold, silver, palladium, or tin. According to other embodiments of the disclosure, the redistribution layer 12 can also be attached to the heat conducting carrier 10 through an adhesive layer 13.

According to an embodiment of the disclosure, the adhesive layer 13 can be formed of various materials, including a polyimide (PI), polyethylene terephthalate (PET), Teflon, liquid crystal polymer (LCP), polyethylene (PE), polypropylene (PP), polystyrene (PS), polyvinyl chloride (PVC), nylon or polyamides, polymethylmethacrylate (PMMA), acrylonitrile-butadiene-styrene, phenolic resins, epoxy resin, polyester, silicone, polyurethane (PU), polyamide-imide (PAI) or a combination thereof, not being limited thereto, as long as such materials have the required adhesive properties.

The bottom (second surface) of the redistribution layer 12 has solder balls 19 electrically connected to the circuit layer 12A at the openings 11 of the heat conducting carrier 10. The solder balls 19 can be implanted on the bottom of the redistribution layer 12 by ball implantation. The semiconductor package device 100 according to an embodiment of the disclosure can be electrically connected to an external device (such as a printed circuit board) by these solder balls 19.

As shown In FIG. 1, an electronic device 16 and electronic components 18 are provided on the top (first side) of the redistribution layer 12. In FIG. 1, only a single electronic device 16 and three electronic components 18 are shown. However, the actual number is not limited to these, and those skilled in the art can set a specific number of electronic devices 16 and electronic components 18 according to actual needs.

The electronic device 16 may be a semiconductor die, a semiconductor chip, or a package including a plurality of electronic devices. The electronic device 16 may be connected to the circuit layer 12A of the redistribution layer 12 via conductive wires such as gold wires, copper wires, or aluminum wires. According to the embodiment of the disclosure, the electronic device 16 may be optoelectronic devices, micro-electromechanical systems (MEMS), power amplifier chips, power management chips, biological identification devices, microfluidic systems, or a physical sensor that measures the changes in physical quantities such as heat, light, and pressure. The electronic device 16 also can also comprise semiconductor chips such as imaging sensor devices, light-emitting diodes (LEDs), solar cells, accelerators, gyroscopes, fingerprint readers, micro actuators, surface acoustic wave devices, process sensors or ink printer heads made by a wafer scale package (WSP) process. The electronic components 18 may be electrically connected to the circuit layer 12A of the redistribution layer 12. According to an embodiment of the disclosure, an electronic component 18 may be a passive component, such as a resistor, a capacitor, an inductor, a filter, an oscillator, and so on. In other embodiments, the electronic component 18 may also be an electronic terminal.

The electronic device 16 and the electronic components 18 can be disposed on the top (first side) of the redistribution layer 12 by a flip-chip packaging, and are electrically connected to the circuit layer 12A in the redistribution layer 12. In addition, the electronic device 16 and the electronic components 18 can also be disposed on the top (first side) of the redistribution layer 12 through an adhesive, and electrically connected to the circuit layer 12A in the redistribution layer 12 by wire bonding.

The molding layer 14 is formed on the redistribution layer 12, surrounds the electronic device 16, and exposes the top surface of the electronic device 16. The molding layer 14 also covers the electronic components 18. According to an embodiment of the disclosure, the material of the molding layer 14 can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

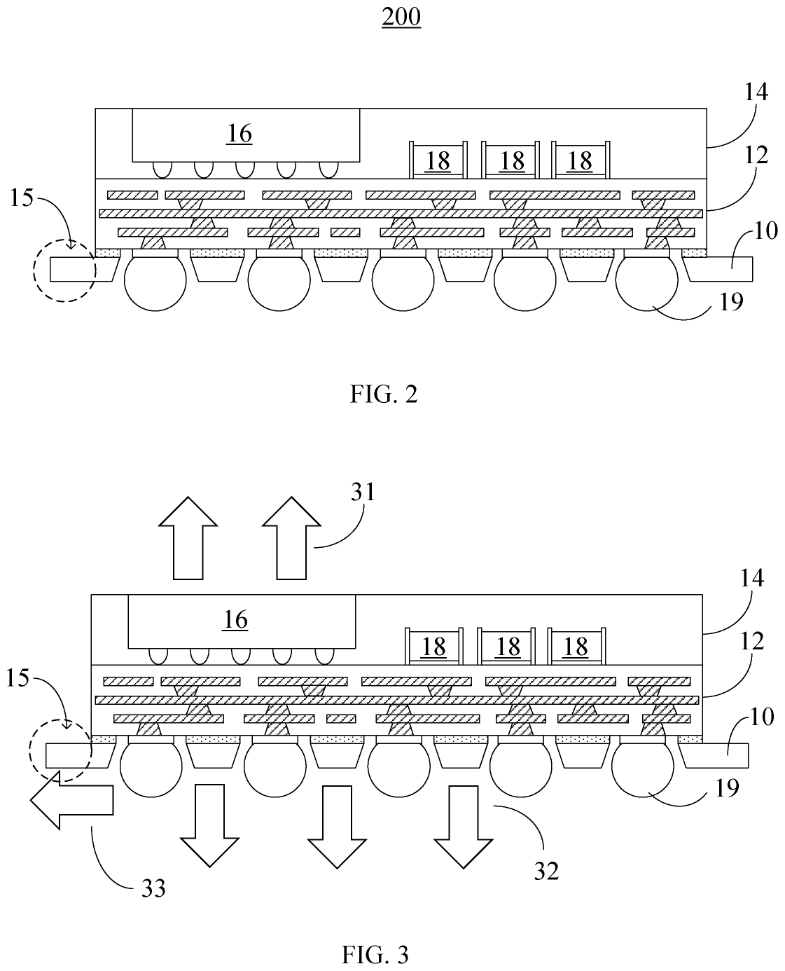

FIG. 2 illustrates a semiconductor package device according to another embodiment of the disclosure (semiconductor package device 200). The difference between the semiconductor package device 200 and the semiconductor package device 100 shown in FIG. 1 is that the heat conducting carrier 10 is not completely covered by the redistribution layer 12, but has an extension 15 that extends parallel to the surface of the heat conducting carrier 10, and beyond the covered area of the redistribution layer 12. The remaining structure of the semiconductor package device 200 is the same as that of the semiconductor package device 100 shown in FIG. 1.

FIG. 3 illustrates heat dissipation layout of the semiconductor package device according to an embodiment of the disclosure. As shown in FIG. 3, the heat generated by the electronic device 16 can be dissipated from the heat dissipation direction 31 through the top, downward from the heat dissipation direction 32 through the heat conducting carrier 10, and from the horizontal heat dissipation direction 33 through the extension 15 of the heat conducting carrier 10, effectively improving the heat dissipation efficiency of the semiconductor package device. In addition, since the thermal conductivity of the molding layer 14 is 3-5 W/m*K, and the circuit layer 12A of the redistribution layer 12 has a small heat dissipation area, the thermal conductivity of the heat conducting carrier 10 made of aluminum nitride is 170 W/m*K or more, so the heat dissipation efficiency of the semiconductor package device is improved.

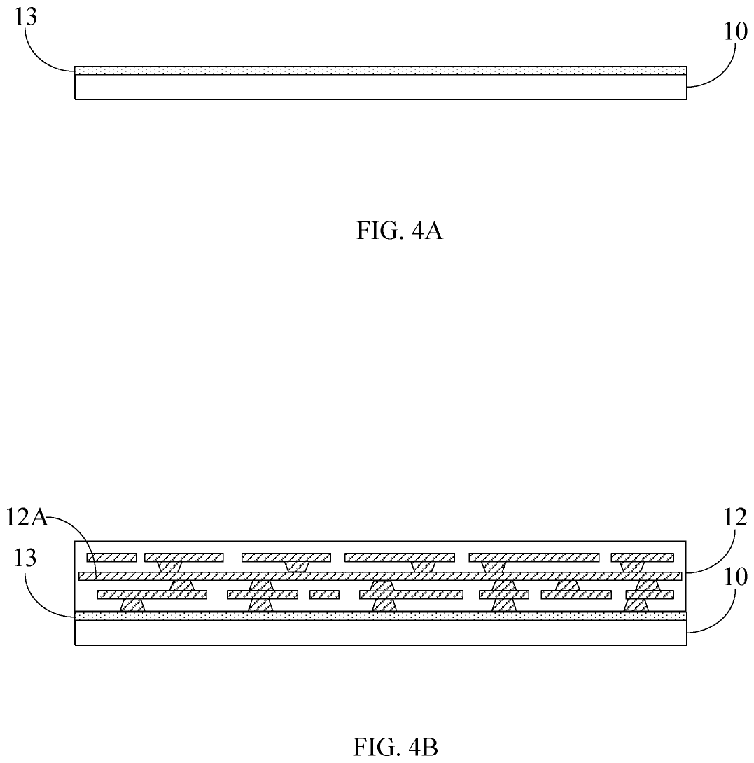

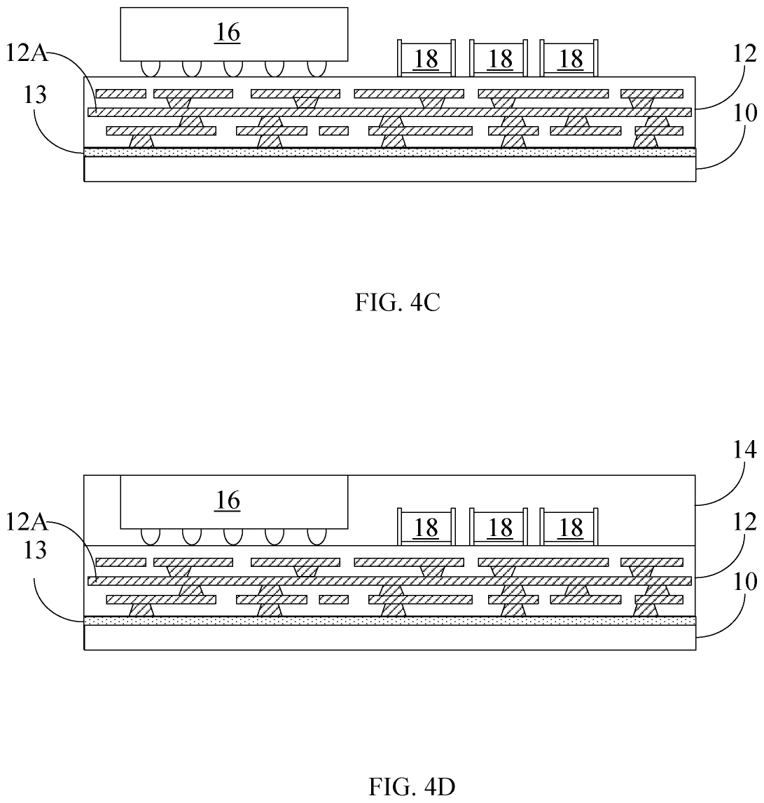

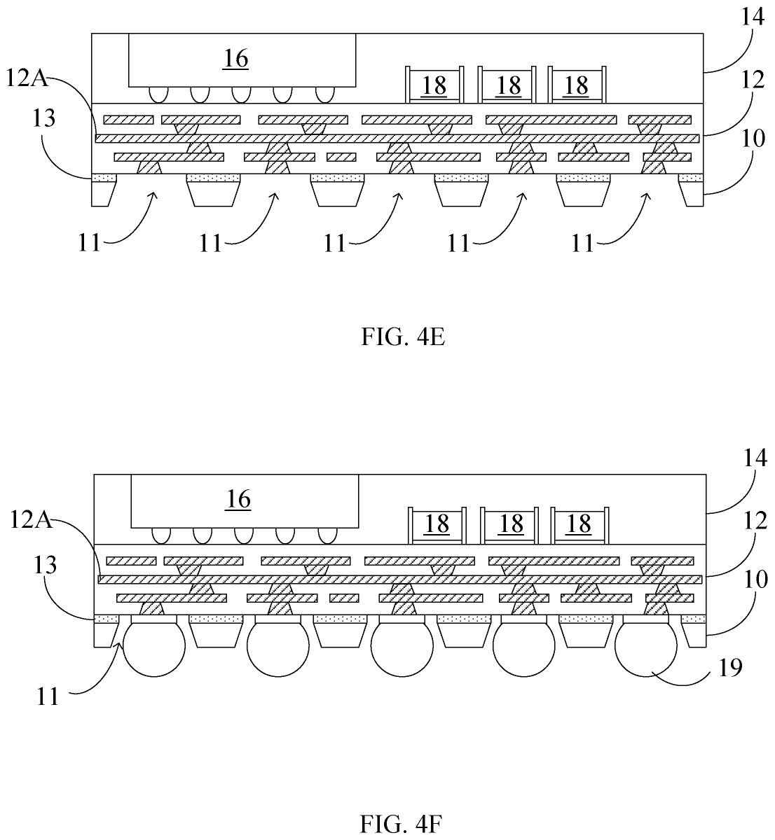

FIGS. 4A-4F illustrate other embodiments for implementation of the method of the disclosure. In FIG. 4A, a heat conducting carrier 10 is provided. The heat conducting carrier 10 is formed of a material with high thermal conductivity, and the thermal conductivity can be in the range of 50 to 5300 W/mK. According to an embodiment of the disclosure, the material of the heat conducting carrier 10 may comprise ceramic, graphene, graphite, carbon nanotube (CNT), carbon nanoball, and aluminum nitride (AlN) or a combination thereof.

Next, an adhesive layer 13 is formed on the heat conducting carrier 10. According to an embodiment of the disclosure, the adhesive layer 13 can be formed of various materials, including a polyimide (PI), polyethylene terephthalate (PET), Teflon, liquid crystal polymer (LCP), polyethylene (PE), polypropylene (PP), polystyrene (PS), polyvinyl chloride (PVC), nylon or polyamides, polymethylmethacrylate (PMMA), acrylonitrile-butadiene-styrene, phenolic resins, epoxy resin, polyester, silicone, polyurethane (PU), polyamide-imide (PAI) or a combination thereof, not being limited thereto, as long as such materials have the required adhesive properties.

In FIG. 4B, the redistribution layer 12 is formed on the heat conducting carrier 10 and has a circuit layer 12A. According to an embodiment of the disclosure, the redistribution layer 12 can be formed layer by layer on the heat conducting carrier 10. In another embodiment, the redistribution layer 12 can be formed on a carrier first, and the carrier then removed after the redistributed layer 12 is coupled to the heat conducting carrier 10. The formation of the redistribution layer 12 may involve multiple deposition or coating processes, patterning processes, and planarization processes. The deposition or coating process can be used to form insulating layers or the circuit layers 12A. The deposition or coating processes may comprise a spin coating process, an electroplating process, an electroless process, a chemical vapor deposition (CVD) process, a physical vapor deposition (PVD) process, an atomic layer deposition (ALD) process, or other applicable processes and combinations thereof. The patterning process can be used to pattern the formed insulating layers and circuit layers 12A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the formed insulating layers and circuit layers 12A to facilitate subsequent processes. The planarization process may comprise a mechanical polishing process, a chemical mechanical polishing (CMP) process, or other applicable processes and combinations thereof.

The redistribution layer 12 can also be formed by an additive buildup process. The additive buildup process may comprise the alternating stacking of one or more dielectric layers and corresponding conductive patterns or traces of the circuit layers 12A. The conductive patterns or traces can fan the electrical traces out of the occupied space of the electronic device, or fan the electrical traces into the occupied space of the electronic device. The conductive patterns can be formed by a plating process such as an electroplating process or an electroless plating process. The conductive pattern may comprise a conductive material, such as copper or other plateable metals. The dielectric layer of the redistribution layer 12 can be made of a photo-definable organic dielectric such as polyimide (PI), benzocyclobutene (BCB), or polybenzoxazole (PBO). In other embodiments, the dielectric material of the redistribution layer 12 may also be an inorganic dielectric layer. The inorganic dielectric layer may comprise silicon nitride (Si₃N₄), silicon oxide (SiO₂), or SiON. The inorganic dielectric layer can be formed by growing an inorganic dielectric layer using an oxidation or nitridation process.

According to the embodiment of the disclosure, the redistribution layer 12 may further comprise a carrier, for example, a printed circuit board (PCB) or a laminated substrate. The carrier can be formed by laminated and build-up methods, which are wholly conventional. The material of the dielectric structure inside the carrier may comprise epoxy resin, phenolic resin, glass epoxy resin, polyimide, polyester, epoxy molding compound, or ceramic. The material of the wires inside the carrier may comprise copper, iron, nickel, gold, silver, palladium, or tin.

Next, as shown in FIG. 4C, an electronic device 16 and electronic components 18 are formed on the top (first side) of the redistribution layer 12. In FIG. 4C, only single electronic device 16 and three electronic components 18 are shown. However, the actual number is not limited thereto, and those skilled in the art can set a specific number of electronic devices 16 and electronic components 18 according to actual needs. The electronic device 16 may be a semiconductor die, a semiconductor chip, or a package including a plurality of electronic devices. The electronic device 16 may be connected to the circuit layer 12A of the redistribution layer 12 via conductive wires such as gold wires, copper wires, or aluminum wires.

According to an embodiment of the disclosure, the electronic device 16 may be optoelectronic devices, micro-electromechanical systems (MEMS), power amplifier chips, power management chips, biological identification devices, microfluidic systems, or physical sensor that measures changes in physical quantities such as heat, light, and pressure. The electronic device 16 also can be semiconductor chips such as imaging sensor devices, light-emitting diodes (LEDs), solar cells, accelerators, gyroscopes, fingerprint readers, micro actuators, surface acoustic wave devices, process sensors or ink printer heads made by a wafer scale package (WSP) process. The electronic components 18 may be electrically connected to the circuit layer 12A of the redistribution layer 12. According to an embodiment of the disclosure, an electronic component 18 may be a passive component, such as a resistor, a capacitor, an inductor, a filter, an oscillator, and so on. In other embodiments, the electronic component 18 may also be an electronic terminal. The electronic device 16 and the electronic components 18 can be formed on the top (first side) of the redistribution layer 12 by a flip-chip packaging, and are electrically connected to the circuit layer 12A in the redistribution layer 12. In addition, the electronic device 16 and the electronic components 18 can also be disposed on the top (first side) of the redistribution layer 12 through an adhesive, and electrically connected to the circuit layer 12A in the redistribution layer 12 by wire bonding.

Next, in FIG. 4D, the molding layer 14 is formed on the redistribution layer 12 and covers the electronic device 16 and the electronic components 18. The molding layer 14 is then polished by a planarization process until the top of the electronic device 16 is exposed. As shown in FIG. 4D, the electronic components 18 are still covered by the molding layer 14. According to the embodiment of the disclosure, the planarization process may comprise a mechanical polishing process, a chemical mechanical polishing (CMP) process, or other applicable processes and combinations thereof. According to an embodiment of the disclosure, the material of the molding layer 14 can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

Next, as shown in FIG. 4E, openings 11 are formed on the heat conducting carrier 10. According to an embodiment of the disclosure, the openings 11 can be formed by mechanical drilling, etching, or laser drilling. Finally, in FIG. 4F, solder balls 19 are placed in the openings 11 on the bottom (second surface) of the redistribution layer 12 and electrically connected to the circuit layer 12A. The solder balls 19 can be implanted on the bottom of the redistribution layer 12 by ball implantation. The semiconductor package device 100 according to an embodiment of the disclosure can be electrically connected to an external device (such as a printed circuit board) by these solder balls 19.

According to the embodiments of the disclosure, the heat dissipation efficiency of the semiconductor package device is improved by the heat conducting carrier. Taking the heat conducting carrier 10 made of aluminum nitride as an example, the thermal conductivity of aluminum nitride exceeds 170 W/m*K, and thermal energy generated by the electronic device 16 can be quickly dissipated through the heat conducting carrier. In addition, the stresses on the heat conducting carrier board 10 made of aluminum nitride are higher than those of the redistribution layer 12. The redistribution layer 12 attached to the heat conducting carrier 10 prevents the redistribution layer 12 from cracking, improving the reliability of the semiconductor products.

Many details are often found in the relevant art and many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A semiconductor package device comprising:
a heat conducting carrier defining an opening;
a redistribution layer formed on the heat conducting carrier, wherein the redistribution layer comprises a circuit layer;
an electronic device disposed on a first surface of the redistribution layer away from the heat conducting carrier;
an electronic component disposed on the first surface of the redistribution layer;
a molding layer formed on the first surface, surrounding the electronic device and covering the electronic component; and
a solder ball disposed in the opening and in contact with a second surface of the redistribution layer opposite to the first surface, the solder ball being electrically connected to the circuit layer.

2. The semiconductor package device of claim 1, wherein the material of the heat conducting carrier is aluminum nitride.

3. The semiconductor package device of claim 1, wherein the material of the heat conducting carrier is ceramics, graphene, graphite, carbon nanotubes, or carbon nanospheres.

4. The semiconductor package device of claim 1, wherein the heat conducting carrier further comprises an extension part extending in a direction parallel to the first surface, and a range covered by the extension parts exceeding a range covered by the redistribution layer.

5. A semiconductor package device, comprising:
a heat conducting carrier defining an opening;
a redistribution layer formed on the heat conducting carrier, wherein the redistribution layer comprises a circuit layer;
an electronic device disposed on a first surface of the redistribution layer away from the heat conducting carrier;
a molding layer surrounding the electronic device; and
a solder ball disposed in the opening, and in contact with a second surface of the redistribution layer opposite to the first surface, the solder ball being electrically connected to the circuit layer, wherein the heat conducting carrier further comprises an extension part extending in a direction parallel to the first surface and a range covered by the extension part exceeds a range covered by the redistribution layer.

6. The semiconductor package device of claim 5, wherein the material of the heat conducting carrier is aluminum nitride.

7. The semiconductor package device of claim 5, wherein the material of the heat conducting carrier is ceramics, graphene, graphite, carbon nanotubes, or carbon nanospheres.

8. A method of manufacturing a semiconductor package device, the method comprising:
providing a heat conducting carrier;
forming a redistribution layer on the heat conducting carrier, wherein the redistribution layer defines a circuit layer, a first surface away from the heat conducting carrier and a second surface adjacent to the heat conducting carrier;
disposing an electronic device and an electronic component on the first surface of the redistribution layer;
forming a molding layer on the first surface and covering the electronic device and the electronic component;
polishing the molding layer to expose a top of the electronic device;
forming an opening on the heat conducting carrier to expose the second surface; and
disposing a solder ball in the opening, the solder ball being in contact with the second surface and electrically connected to the circuit layer.

9. The method of claim 8, wherein the material of the heat conducting carrier is aluminum nitride.

10. The method of claim 8, wherein the material of the heat conducting carrier is ceramics, graphene, graphite, carbon nanotubes, or carbon nanospheres.

11. The method of claim 8, further comprising providing the heat conducting carrier with an extension part, wherein the extension part extends in a direction parallel to the first surface and a range covered by the extension part exceeds a range covered by the redistribution layer.

12. The method of claim 8, wherein the opening on the heat conducting carrier is formed by mechanical drilling, etching or laser drilling.
